(19) United States
(12) Patent Application Publication
(10) Pub. No.: US 2001/0036602 A1
(43) Pub. Date: Nov. 1, 2001

(54) Analog relief microstructure fabrication

(76) Inventors: Stephen P. McGrew, Spokane, WA (US); Robert O. Warrington, Ruston, LA (US)

Correspondence Address: Edward W. Bulchis, Esq., DORSEY & WHITNEY LLP, Suite 3400, 1420 Fifth Avenue, Seattle, WA, 98101, US

(21) Appl. No.: 09/805,713

(22) Filed: Mar. 13, 2001

Related U.S. Application Data
(63) Continuation of application No. 08/900,068, filed on Jul. 24, 1997, now abandoned.

(51) Int. Cl. G03F 9/00

(52) U.S. Cl. 430/321; 430/320; 430/967; 430/5

(57) ABSTRACT

A microfabrication technique, applications thereof, and mass-manufacturing techniques therefore, in which an analog mask is created and used to control exposure of a resist material to actinic radiation in order to create analog products at the microscale.

### BACKGROUND OF THE INVENTION

1. Field of the Invention

The present invention concerns a method and apparatus for fabricating three-dimensional microstructures using a modified deep x-ray lithography process, and products whose manufacture is made possible thereby. The invention has particular utility in the fabrication of micromachinery, including motors, fluidic devices, distillation systems, engines, accelerators, compressors, pumps, venturi devices, and centrifuges, combined diffractive-refractive micro-optics, microlenses, fiber-optic connectors and the like.

2. Description of Related Information

A high level of interest exists today in micromachinery, which promises a number of important advantages. In addition to the many advantages associated with the compact design of micromachinery, micro-miniaturization may be used to harness physical effects that appear only at the microscale. Micromachinery is typically characterized by feature sizes on the order of microns, and by component dimensions on the order of tenths of millimeters and greater.

Major reductions in the size and mass of components are sought in areas too numerous to document, including the space program. As an example, miniaturized heat pumps that use micromachined fluid pumps as small as a cubic millimeter may be used in applications as diverse as thermal management on space vehicles, home air-conditioning, communications, computer systems, infrared sensors and cooled infrared imaging arrays, and superconductive sensors and electronics. Microtechnology is expected to improve performance, endurance and survivability in these and other systems.

In the past, various techniques were employed for fabricating micromachinery components, including deep x-ray lithography. Deep x-ray lithography uses synchrotron x-ray exposure to fabricate microstructures in resist material such as Polymethylmethacrylate (PMMA). An x-ray resist such as PMMA will more readily dissolve in certain solvents when it has been exposed to x-ray radiation.

By selectively exposing the x-ray resist to radiation, and then rinsing the x-ray resist in a dissolving solution such as Methylethylketone (MEK), a desired resist topography may be obtained. Selective exposure may be controlled by the use of a radiation-absorbing mask between the x-ray source and the x-ray resist. The process has been used to achieve lateral resolutions on the order of one micron and height-to-width aspect ratios on the order of 200 to 1, where “lateral resolution” represents the fineness of detail achievable in the plane of the resist.

The deep x-ray process was developed specifically to produce deep microstructures, with width on the order of 10 to 100 microns, and depth up to a centimeter, which are desirable in fabricating micromachinery. Ordinary optical microlithography cannot produce deep microstructures because (a) light is diffracted too readily by structures on the size scale of interest, such that the light pattern a few microns beyond the mask is no longer the same as it is at the mask and (b) light tends to be strongly absorbed by the resist making it ineffective in producing uniform exposures. On the other hand, x-rays have very short wavelengths so diffraction is not a problem. X-rays are also highly penetrating so they can produce uniform exposures in thick materials. Finally, x-rays are very energetic so that they can break chemical bonds in materials that are not sensitive to light.

Deep x-ray lithography as practiced in the past was fundamentally two-dimensional, in that it primarily produced structures having only two possible heights. This was because masks previously used in connection with deep x-ray lithography generally comprised a pattern of regions that were either opaque to x-rays or transparent (“binary” masks). The resulting resist structures were consequently binary, two-level structures. The x-rays would pass through transparent regions creating valleys in the resist, but would be blocked in opaque regions leaving peaks in the resist.

It is desirable to fabricate microscale components having multi-level relief structures, including approximately curved surfaces wherein the height of a resist structure varies smoothly across a portion of the resist (hereinafter, an “analog” relief pattern). As compared with binary structures, analog structures may be used to fabricate micromechanical and micro-optical products which are less expensive, more efficient and more effective than their binary counterparts.

For example, a micropump or microcompressor typically incorporates a flexible membrane which is disposed above a shallow chamber. When the membrane is deflected into the chamber, it compresses the fluid or gases therein. The resulting pressure is reduced if the membrane cannot conform to the chamber. In fact, the compression ratio depends strongly, on how well the shape of the chamber conforms to a paraboloid, which is an approximation to the. shape of the membrane at maximum deflection. Compression ratio is also extremely important in the design of refrigerators, engines, and other such devices, all of which have their micro-analogues.

Although use of binary masks in connection with deep x-ray lithography can be adapted to produce stepped structures with a larger number of levels, such adaptations are very expensive, very time-consuming, and tedious. For example using multiple masks requires a series of separate exposures using different binary masks. In this manner, the total exposure at a given step may be varied to approximate an analog pattern. For example, using binary masks to create a structure having 64 possible depths would require at least 6 exposure steps with a different mask properly positioned for each step. The 6 exposures could be done at 1, 2, 4, 8, 16 and 32 times a base exposure level, resulting in a net exposure of 0 to 63 times the base exposure at each point.

The difficulty with this approach is that the mask must be changed between exposures, which introduces or magnifies the risk of alignment error and adds time and effort to the process. In addition, continuous, curved surfaces such as paraboloids, as are necessary for high performance heat pumps, can only be approximated crudely using this method.

Analog structures may be produced in electron beam resist with thicknesses up to 15 microns. New Light Industries, Ltd. has developed a binary electron beam exposure technique which allows unprecedented precision: 5 nanometers in the vertical dimension and 100 nanometers in the lateral dimensions. The New Light Industries process permits specification of point-to-point feature heights with a precision better than 10 nanometers. The process is explained in SBIR Phase I Final Report, “A New High-Resolution, High-Speed Spatial Light Modulator,” NASA Contract No. NAS2-13784 (Aug. 26, 1993), the entire disclosure of which is incorporated herein by reference.

Care should be taken to distinguish between the two meanings of the term “binary” as used above. A “binary” mask has two possible transmissivity values at each point. A “binary” relief structure has two possible height or depth levels. An “analog” mask has several levels of transmissivity. An “analog” relief structure can be created by sequential exposures through binary masks (through “binary synthesis”) or by a single exposure through an analog mask.

Although the New Light Industries process may be used to fabricate analog structures, the structures are generally only a few microns long and half a micron high, which is smaller than is desirable for most micromachinery applications.

A need exists therefore for technology which will give micromachine designers analog control of the vertical dimensions of their structures, enabling creation of deep microstructures having analog shapes such as domes, cups, dishes, lenses, toroids, ramps, chutes, valleys and hills, and enabling the fabrication of micromachinery with substantially improved power and efficiency. Such a technology should allow production of analog relief patterns at the microscale at reasonable cost and within a reasonable time.

### SUMMARY OF THE INVENTION

The present invention overcomes the above-mentioned disadvantages and drawbacks which are characteristic of the related information. In a preferred embodiment, the invention employs an analog x-ray mask fabricated using electron beam technology, in connection with deep x-ray lithography, to fabricate deep, analog structures in resist material, for ultimate use in connection with the fabrication of micromachinery.

In a preferred embodiment, a thin analog mask is first fabricated using electron beam technology and chemically assisted ion etching. The analog mask is made of an actinic radiation absorbing substance, such as gold, such that absorption of actinic radiation (including x-rays and energetic electrons or ions) at a given point is a function of the local thickness of the mask.

In a preferred embodiment, the analog mask is placed in between an x-ray source and a block of x-ray resist, and is used in lieu of a conventional binary mask to control x-ray exposure of the resist. The analog mask absorbs radiation according to its thickness, resulting in an analog distribution of exposure within the x-ray resist. When the resist is developed, the x-ray exposure pattern results in an analog structure.

The x-ray resist may be a separate block or may be predisposed as a layer below the mask prior to electron beam fabrication of the mask itself. In this embodiment, the gold mask may be dissolved after exposure (using cyanide, for example) after which the resist may be developed as above.

In a preferred embodiment, the total x-ray exposure through the mask and to the x-ray resist may be adjusted according to the extent to which x-ray penetration is desired. Due to the relationship between energy level, exposure duration, and penetration, a longer exposure period or the use of higher energy radiation may effectively amplify the vertical dimensions of the mask as its relief pattern is transferred into the x-ray resist.

In this manner, a thin analog mask may produce resist structures which have the same lateral dimensions as the mask but which have much greater vertical dimensions. If a deep mask is desired, the thin analog mask may be used to produce an amplified deep resist structure, which may be ion etched into an underlying layer of mask material to produce a deep mask.

In a preferred embodiment, the aforementioned masks and x-ray resist structures may be mass replicated or mass produced using various techniques according to the present invention.

In one such embodiment, one or more reverse replicas of a mask or microstructure may be created by molding processes well understood in the art, and may be attached around a cylinder to form a reusable embossing tool. Replicas of the mask or microstructure may then be formed by embossing the reverse replicas onto a desired material.

If duplicate masks are required, the reverse replicas may be embossed onto a polymer layer coated onto a layer of mask material. Duplicate analog masks may then be formed by transferring the embossed polymer relief patterns into the mask material layer using chemically assisted ion etching.

In another embodiment, an embossed reverse replica of a microstructure (final product or mask) formed in a first material may be laminated onto the surface of a layer of a second material, and the microstructure may be transferred into the second material by ion etching the first material into the second material.

In yet another embodiment, a hard version of an analog mask, which may be formed in resist or created using electroforming and other processes well understood in the art, may be pressed onto a deformable layer of mask material disposed above an x-ray resist substrate, such that the hard relief pattern deforms the soft mask material, forming a reverse replica of the original mask.

In yet another embodiment, a layer of mask material may be filled in above the resist relief pattern, and the combined structure may function as a mask. Filling may be accomplished by electroforming or similar means, followed by planarization such as may be accomplished by grinding and polishing. In another embodiment, the electroformed layer of mask material may be “peeled” off the resist relief pattern and laid on a new x-ray resist block.

In yet another embodiment, a gelatin layer having an analog relief pattern may be placed on a substrate. The gelatin may be swollen in water, or another solvent, and then permeated with gold (or other mask material) in solution. The resulting structure may be dried and used as a mask.

In yet another embodiment, a microstructure formed in a first material may be duplicated in a second material by investment/lost wax casting or similar means.

In a preferred embodiment of the present invention, a high-efficiency micromachine, for use in connection with a micropump, microcompressor, or analogous device, may be fabricated using a microscale parabolic dish created according to the aforementioned analog mask processes. In a preferred embodiment, the dish has a central cavity connected to an underlying channel. A deformable membrane is disposed above the dish such that when the membrane is deflected into the dish, the membrane shape substantially corresponds to the interior dish shape, resulting in a high compression ratio.

Numerous other objects, features and advantages of the present invention will be readily apparent to those of ordinary skill in the art upon a reading of the following detailed description of presently preferred but nonetheless illustrative embodiments of the present invention when taken in conjunction with the accompanying drawings.

### BRIEF DESCRIPTION OF THE DRAWINGS

FIG. 1 shows a working block according to the present invention before processing;

FIG. 2 shows the working block of FIG. 1 after electron beam exposure and development;

FIG. 3 shows an analog mask according to the present invention (also shows the working block of FIG. 2 after ion etching);

FIG. 4 shows an apparatus for deep x-ray lithography according to the present invention;

FIG. 5 shows the x-ray resist block of FIG. 4, after amplifying x-ray exposure, removal of the mask layer, and development;

FIG. 6 shows a mask material layer filled above an analog relief pattern;

FIG. 7 shows an embossing tool and embossing method according to the present invention;

FIG. 8 shows a hard reverse replica of a master relief pattern used as an embossing die to create a replica of the mask relief pattern in a deformable x-ray absorbing material.

FIG. 9 shows an investment casting method according to the present invention;

FIG. 10 shows a micromachine as fabricated in the past for use in connection with micropumps, microcompressors, and analogous devices; and

FIG. 11 shows a micromachine according to the present invention, for use in connection with micropumps, microcompressors, and analogous devices.

### DESCRIPTION OF THE PREFERRED EMBODIMENTS

A preferred embodiment of the present invention relates to a process and apparatus for fabricating deep analog microstructures.

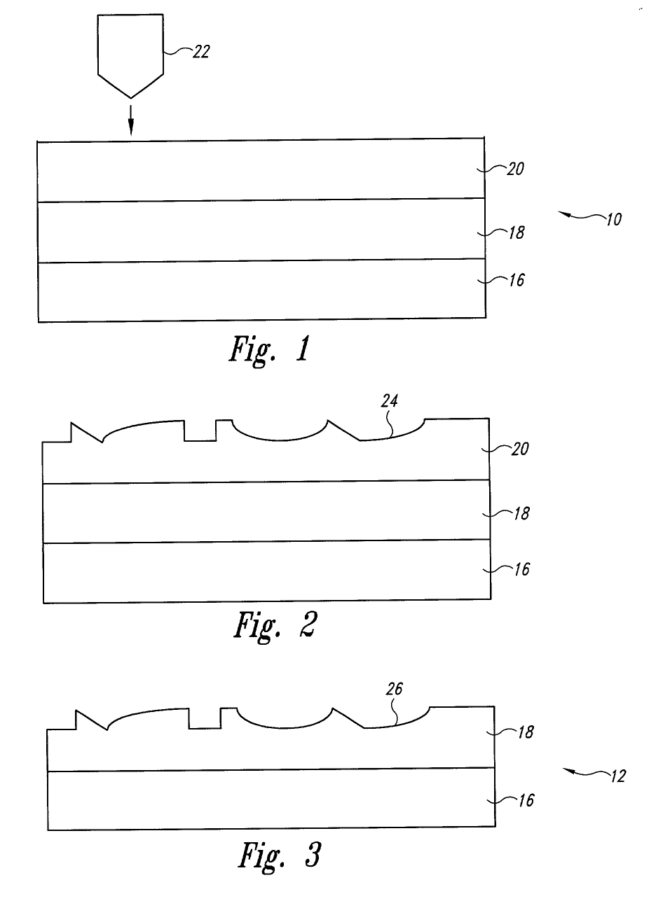

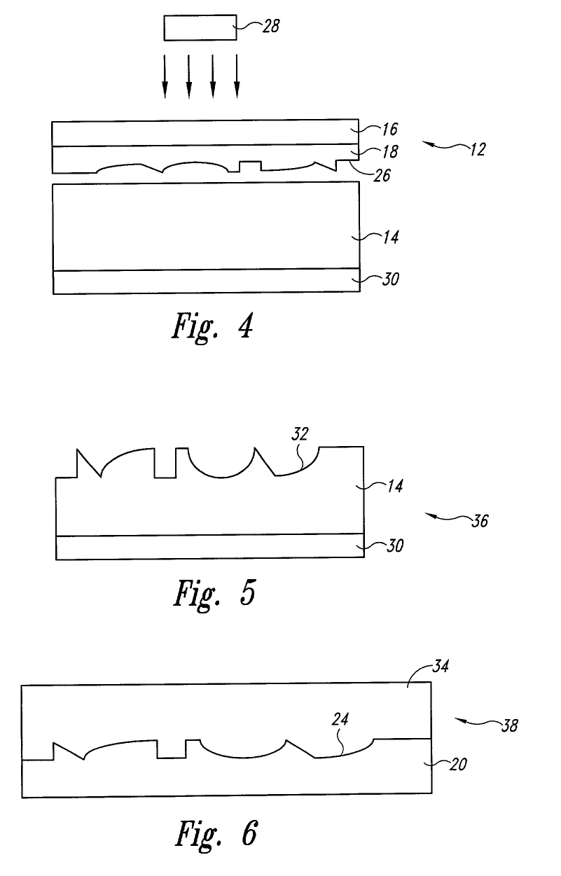

Referring now to the drawings, and particularly FIGS. 1-5, a preferred embodiment of the present invention employs a multi-layered working block 10, which is used to produce an analog mask 12 (FIG. 3) having desired analog relief characteristics. In a preferred embodiment, deep x-ray lithography is subsequently applied (FIG. 4) through the analog mask 12 to produce a vertically amplified replica 36 (FIG. 5) of the mask 12 in x-ray resist 14.

In a preferred embodiment, the working block 10 comprises three consecutive layers: a substrate layer 16, a mask material layer 18, and an electron beam (“e-beam”) resist layer 20. In a preferred embodiment, the e-beam resist layer 20 is composed of PMMA, the mask material layer 18 is composed of gold, and the substrate layer 16 is composed of beryllium. The e-beam resist layer 20 and the mask material layer 18 are preferably uniform and approximately 0.5 to 3.0 microns thick.

In the first step of a preferred method according to the present invention, the e-beam resist layer 20 is contoured to an analog relief pattern using electron beam technology. The e-beam resist layer 20 is first exposed pattern-wise by an electron beam source 22 whose travel rate may vary from point to point, so as to vary the net exposure at each point according to a desired pattern. An electron beam may be focused down to about 0.1 microns, and positioned with an accuracy of about 0.05 microns, so as to generate patterns with features as small as 0.1 microns.

By varying the net exposure at each point, it is possible to generate analog rather than binary exposure patterns which are smooth to a scale of 0.1 microns. By spreading the beam wider, it is possible to produce patterns with smoother exposure gradations, but with lower lateral resolution. For micromechanical devices whose features are on the scale of tens or hundreds of microns, smoothness to a scale of 0.1 microns is perfect smoothness for most practical purposes.

Those of ordinary skill in the art will recognize that the selections of resist materials and types of radiation need only be complementary. Any radiation to which the resist is sensitive, and which is capable of penetrating the resist to a suitable depth, will serve in place of electron beam or x-ray radiation (e.g., gamma rays, visible light or ultraviolet light). Likewise, any resist that is sensitive to the selected radiation is suitable.

Because the analog mask 12 will be used to control x-ray radiation, the substrate layer 16 may be any substantially x-ray transparent material and the mask layer 18 may be any x-ray absorbing material (including gold and others). Maximizing the contrast in absorbance between the substrate layer 16 and the mask material layer 18 is most important for high-contrast exposure, while minimizing absolute absorbance by the substrate layer 16 is most important for minimizing total exposure needed to attain a desired net exposure of the e-beam resist layer 20.

According to a preferred method, the e-beam resist layer 20 is developed following exposure to produce a desired analog relief pattern 24, as is shown in FIG. 2. The e-beam resist layer 20 is developed by rinsing the e-beam resist layer 20 in a solvent for which there is a substantial difference between dissolution rates in areas of the resist receiving different amounts of radiation exposure. In a preferred embodiment, the solvent is MEK.

The development of the e-beam resist layer 20 removes resist material to varying depths according to the radiation exposure the resist received at each point, thus resulting in a relief pattern 24 in the e-beam resist layer -20 which exhibits substantially continuous depth variation corresponding to a continuously varying pattern of radiation. At this stage, the relief pattern 24 exists only in the e-beam resist layer 20 because the exposure and the solvent have no effect on the mask material layer 18 or the substrate layer 16.

The relationship between exposure and etch depth is nonlinear. However, those of ordinary skill in the art will recognize that the depth of propagation in the e-beam resist layer 20 may be predicted by characterizing the depth-exposure function for the particular selected combination of type of actinic radiation, type of resist and development process. In this manner, penetration may be calibrated and predicted.

According to a preferred method, the relief pattern 24 in the e-beam resist layer 20 is next transferred to the mask material layer 18 using reactive ion etching. By this method, relief structures created in the e-beam resist layer 20 with a thickness up to about 10 microns can be transferred into an underlying layer of mask material having about the same thickness.

Reactive ion etching is an anisotropic etch process which removes material at an essentially constant rate measured in the direction of the velocity vector of the ions in the etch beam. Thus, the etch beam penetrates a roughly constant distance below the surface of the relief pattern 24 in the e-beam resist layer 20 and into the mask material layer 18, such that the relief pattern 24 in the e-beam resist layer 20 propagates downward into the mask material layer 18. Those of ordinary skill in the art will recognize that other anisotropic etching processes may be substituted for ion etching.

The e-beam resist layer 20 is removed completely in the etching process, and the mask material layer 18 is thereby etched to conform to an accurate replica 26 of the original relief pattern 24 in the e-beam resist layer 20. In a preferred embodiment, as shown in FIG. 3, the combination of the etched mask material layer 18 having a relief pattern 26, and the substrate layer 16 comprises an analog mask 12.

The most likely and significant difference between the relief pattern 24 in the e-beam resist layer 20 and the transferred relief pattern 26 in the mask material layer 18 is a difference in vertical scale. The relative vertical scales are a function of the relative etch rates of the mask and resist materials, which are in turn a function of the ion type and the extent to which other gases are introduced into the etching environment. Introduction of other gases into the etching environment is a process known as chemically assisted ion etching, which can be used to amplify the vertical scale in the mask material layer relative to the e-beam resist layer.

Etch rate differences may be used to fine-tune the vertical scale. The absolute final etch depth will depend on development temperature, choice of solvent, total exposure, mask material, mask substrate material, mask thickness, choice of x-ray resist and e-beam resist, choice of x-ray exposure wavelength and other variables. Those of ordinary skill in the art will recognize that the process can be calibrated by developing a depth-exposure function through a systematic process in which certain parameters are fixed and others are varied.

The analog mask 12 may also be fabricated using alternate methods including the use of a narrow or broad radiation beam passing through another analog mask whose transmissivity to the radiation varies according to the desired exposure pattern. Those of ordinary skill in the art will recognize that an analog mask created using a sequence of separate binary exposures may also be used in the inventive embodiments that follow.

As is shown in FIG. 4, in the next step of a preferred method according to the present invention, the analog mask 12 is used to control radiation exposure of an x-ray resist layer 14 on the order of one centimeter thick and greater. The analog mask 12 is placed in close proximity to, or in contact with the layer of x-ray resist 14, such that the mask 12 is between a synchrotron x-ray source 28 and the x-ray resist layer 14. In a preferred embodiment, the x-ray resist layer 14 is connected with a substrate 30.

X-rays are passed through the analog mask 12 to expose the x-ray resist layer 14. The quantity of x-rays transmitted by the mask 12 and received by the x-ray resist layer 14 varies smoothly over the mask 12 and x-ray resist layer 14 in accordance with the smoothly varying pattern of thickness in the mask 12.

X-rays are capable of exposing the x-ray resist layer 14 to a greater depth than is the electron beam 22 used to create the relief pattern 24 in the e-beam resist layer 20. If the x-ray beam is too narrow or too nonuniform to expose the x-ray resist layer 14 evenly, it can be scanned to produce a uniform net illumination over the whole mask area. Once exposed, the x-ray resist layer 14 is rinsed in a solvent, such as MEK, thereby producing a deep relief pattern 32 the depth of which varies smoothly at each point according to the mask pattern.

Using sufficient exposures of x-ray radiation, a deep relief pattern 32 may be fabricated in the x-ray resist layer 14, essentially amplifying the relief pattern 26 of the mask 12.

The relief structure 32 may also be fabricated using a radiation beam which passes through the mask 12 and is subsequently focused onto the resist material 14 by an appropriate optical system thereby forming an image of the mask on the resist material. Such an optical system may comprise diffractive x-ray optics, grazing incidence reflective optical elements, or x-ray lenses made of a material having an atomic resonance close to the x-ray frequency used, such that the material has a high effective incidence of refraction at the x-ray frequency.

Those of ordinary skill in the art will recognize that the mask thickness profile may be calibrated by determining a depth-exposure curve to reflect depth of x-ray exposure in a given x-ray resist material as a function of mask thickness. Such a function may be used to compensate for nonlinearities in the relationship between penetration and exposure with deep x-ray lithography.

In a preferred embodiment of the present invention, the x-ray resist layer 14 may be initially disposed beneath the mask material layer 18 of the working block 10 in place of the beryllium substrate layer 16. The electron beam radiation and ion etching may be controlled so as to not affect the x-ray resist layer 14 while the e-beam resist 20 and mask material layer 18 are exposed, developed, and etched. For example, an electron beam voltage that is too low to penetrate the mask material layer 18 may be used to expose the e-beam resist layer 20.

The combined mask-resist combination may then be exposed to x-ray radiation as described above, and the mask material layer 18 may be subsequently removed in a cyanide bath. Other layers may be added below the substrate layer 16, or in lieu of the substrate layer 16, to further simplify or adapt-post-processing of the block 10.

There are several alternative methods according to the present invention by which an original shallow relief pattern in the e-beam resist layer 20 may be used to create an analog mask 12. According to one such method, as is shown in FIG. 6, the surface of the e-beam resist layer 20 having a relief pattern 24 may be filled with an x-ray absorbing material 34, and the resulting combined structure may be used as a mask 38. Alternatively, a thin foil 34 of x-ray absorbing material may be electroformed onto the surface of the e-beam resist layer 20, then planarized, and the resulting structure 36 may be used as an analog mask 12.

According to another preferred method, a thin relief pattern may be fabricated in a resist material such as dichromated gelatin. The resist may then be swollen in a solvent such as warm water. Subsequently, an x-ray absorbing substance such as gold may be deposited by diffusion and absorption into the dichromated gelatin. The resulting structure may be dried and used as an analog mask.

In yet another method, an analog mask for use with an optical system to project a pattern onto resist may be fabricated as a diffractive structure whose zero-order diffraction varies from point to point. In this case, the mask material does not have to absorb x-rays; it can merely shift the phase of x-rays passing through it. Then, a sufficiently coherent x-ray beam will be diffracted according to the amplitude of the diffractive structure, leaving only the zero-order portion to expose the resist material.

In another preferred embodiment of the present invention, a mass-manufacturing method for fabricating deep analog structures comprises the steps of (a) patterning masks, (b) replicating masks, (c) exposing resist through the mask(s), and (d) replicating the final x-ray resist product. Those of ordinary skill in the art will recognize that the steps in the mass-manufacturing method may be used singly or in combination.

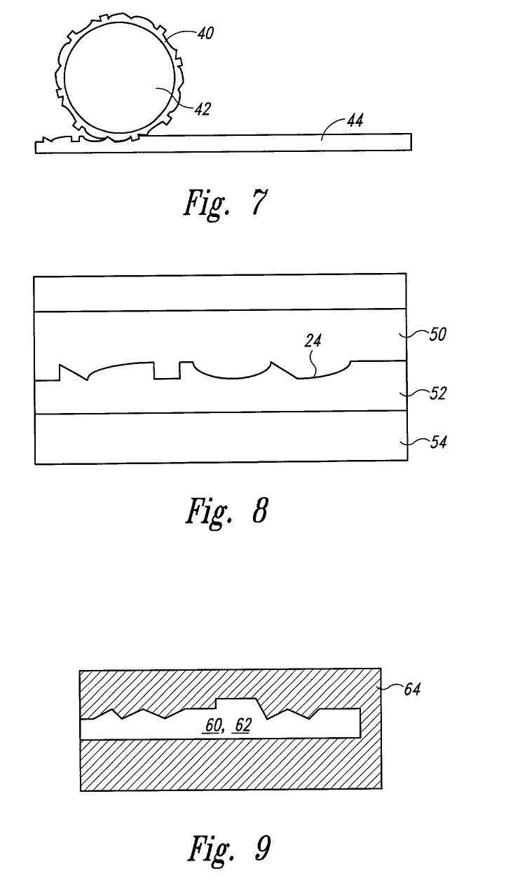

The relief pattern 26 of the mask 12, and any other relief pattern, may be reverse replicated according to embossing techniques well understood in the art. In a preferred embodiment, shown in FIG. 7, a nickel reverse replica 40 of a final x-ray resist product 36 or a mask 12 may be formed by electroplating nickel onto the original microstructure. The nickel replica 40 may then be removed, wrapped around a cylinder 42, and used as an embossing tool to emboss the relief pattern of the original microstructure into another material 44.

Those of ordinary skill in the art will recognize that reverse replicas may be created using other molding processes including embossing, UV resin casting, thermoset molding, thermoforming, epoxy casting or electroless metal deposition. In the UV resin casting process,. a UV curable resin may be applied to a relief pattern, and peeled off after it is cured (solidified) by exposure to UV light. The process is described in U.S. Pat. No. 4,758,296, the entire disclosure of which is incorporated herein by reference.

To create a large number of replicas of x-ray resist structures, the nickel embossing tool may be used repeatedly to emboss the original relief into deformable materials. The relief may then be transferred into harder materials, using etching, investment casting, or electroforming for example.

To replicate a mask, a nickel replica may be embossed into a polymer coating applied to a mask material layer which overlies an x-ray resist substrate. In a preferred embodiment, the mask material layer is composed of gold, the x-ray resist substrate is composed of PMMA, the polymer coating is on the order of 2 microns thick, and the mask material layer and PMMA substrate layer are on the order of 3 microns thick.

The substrate with its overlying layers, including the embossed polymer layer, may be reactive ion etched to transfer the relief pattern in the polymer layer into the underlying gold layer. The gold layer thereby acquires a relief pattern corresponding to the original relief structure, with essentially the same vertical scale. This gold layer may then serve as an analog mask for x-ray exposure of the PMMA substrate. Subsequent to PMMA exposure, the gold layer may be dissolved off in a cyanide solution, after which the PMMA substrate may be developed as discussed above using MEK. The resulting final PMMA relief is the desired analog microstructure.

Referring now to FIG. 8, in another preferred embodiment, a hard, durable reverse replica 50 of a relief pattern 24 in an e-beam relief layer 20 may be produced by a method such as electroforming. The hard version of the relief pattern 50 may then be used to emboss the relief pattern 24 into a layer of deformable, x-ray absorbing material 52, such as gold, on a suitable substrate 54, thereby directly forming an analog mask, as opposed to ion etching.

The deformable radiation-absorbing material 52 may be coated onto the substrate 54 by vapor deposition or other such process, to a thickness slightly greater than that necessary to provide the required relief depth of the mask. In principle, the required thickness is somewhat less than the maximum depth of the relief pattern 24, since the deformable material 52 is deformed by embossing in such a way that it is displaced by elevations in the embossing tool and migrates to fill depressions in the embossing tool.

In yet another preferred embodiment, shown in FIG. 9, final x-ray resist product in one material 60 may be formed in a second material 62 by surrounding the original with an investment material 64, melting, evaporating, dissolving or burning the first material 60 away, and filling the void with the second material 62. As an example, this embodiment would be desirable as a means to create a metal microstructure from a PMMA master.

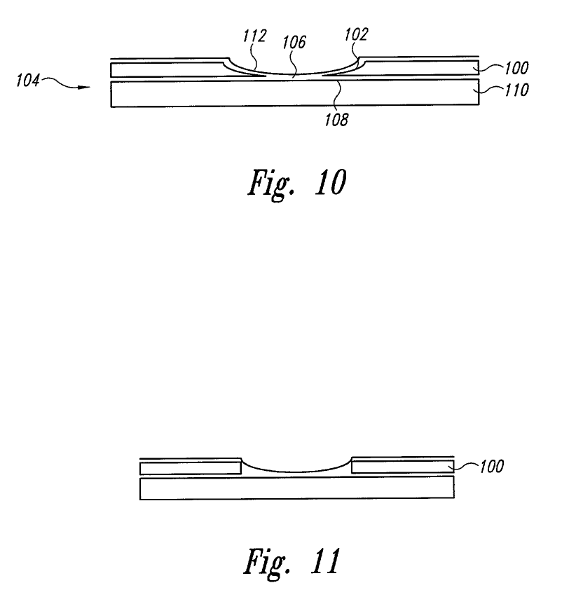

Referring now to FIG. 10, yet another embodiment of the present invention employs a microstructure 100 having an analog dish 102, created according to the present invention, to form a micropump, microcompresser, or analogous micromachine 104. An analogous micromachine, as practiced in the past, is shown in FIG. 11.

In a preferred embodiment, the analog dish 102 is preferably parabolic and has an outlet 106 at its center which is hydraulically connected with a channel 108 filled with fluid or gas that passes beneath the dish 102. Those of ordinary skill in the art will recognize that the channel 108 below the dish 102 may be fabricated in a variety of ways. For example, the microstructure 100 containing the dish 102 may be laminated onto a layer of material 110, into which the channel 108 has been precut, such that the outlet 106 is aligned above the channel 108.

In a preferred embodiment, the micromachine 104 also has a piezoelectric deformable membrane 112 which covers the top of the dish 102. When the membrane 112 is in its relaxed state, it is flat. When the membrane 110 is deformed toward the channel 108, liquid or gas collected in the dish 102 is forced out of the dish 102 and into the channel 108. Those of ordinary skill in the art will recognize that the deformable membrane 112 may be driven by other than piezoelectric means.

In a preferred embodiment, the shape of the dish 102 is complementary to the shape of the deformed membrane 112 such that the majority of the gas or liquid in the dish 102 is forced out when the membrane 112 is deformed, resulting in an extremely high compression ratio.

While the present invention has been described in detail and with reference to specific embodiments thereof, it will be apparent to one of ordinary skill in the art that various modifications can be made therein without departing from the spirit and scope of the invention and the appended claims which are intended to cover all such modifications.

What is claimed is:

1. A method for fabricating analog microstructures comprising the steps of:
a) fabricating an analog mask comprising a layer of mask material, said mask material absorbing a variable amount of a first type of radiation, wherein said amount of absorption varies with the thickness of said mask material layer;
b) directing said first type of radiation through said analog mask to expose a first resist material to said first type of radiation; and
c) creating an analog relief in said first resist material by exposing said first resist material to a first solvent, wherein said first solvent dissolves said first resist material at different rates depending on the amount of exposure of said first resist material to said first type of radiation.

2. A method according to claim 1 wherein said first resist material is integral with said analog mask.

3. A method according to claim 1 wherein said first type of radiation is selected from a group consisting of actinic radiation and x-ray radiation.

4. A method according to claim 3 wherein said first resist material comprises polymethylmethacrylate.

5. A method according to claim 3 wherein said radiation absorbing material comprises a material from the group consisting of gold and tungsten.

6. A method according to claim 3 wherein said first solvent comprises methylethylketone.

7. A method according to claim 3 wherein said gold mask comprises a substrate that is transparent to said x-ray radiation.

8. A method according to claim 7 wherein said substrate comprises beryllium.

9. An analog microstructure produced by the process of claim 1.

10. A method according to claim 1 wherein said analog mask is fabricated using a method comprising the steps of:
a) fabricating a working block having a plurality of layers, wherein a first layer comprises a second resist material sensitive to a second type of radiation, and a second layer comprises said mask material;
b) exposing said second resist material to said second type of radiation in an analog exposure pattern;
c) creating an analog relief in said first layer by exposing said second resist material to a second solvent, wherein said second solvent dissolves said second resist material at different rates depending on the amount of exposure of said second resist material to said second type of radiation; and
d) transferring said analog relief of said first layer to create an analog relief in said second layer using anisotropic etching.

11. An analog microstructure produced by the process of claim 10.

12. A method according to claim 10 wherein said second type of radiation comprises electron beam radiation, and wherein said analog exposure pattern is created by exposing said second resist material to a variable electron beam dose corresponding to said pattern.

13. A method according to claim 10 wherein said anisotropic etching comprises ion etching.

14. A method according to claim 10 wherein said second resist material comprises polymethylmethacrylate.

15. A method according to claim 10 wherein said analog mask is made integral with and disposed above said first resist material prior to exposing said second resist material.

16. A method according to claim 10 wherein said second solvent comprises methylethylketone.

17. A method according to claim 10 wherein said working block further comprises a third layer comprising a substrate material.

18. A method according to claim 1 further comprising the step of amplifying the vertical scale of said analog mask in said first resist material.

19. A method according to claim 18 wherein said amplification is accomplished by extending the duration of exposure of said first resist material to said first type of radiation.

20. A method according to claim 18 wherein said amplification is accomplished by increasing the intensity of exposure of said first resist material to said first type of radiation.

21. A method according to claim 18 wherein said amplification is accomplished using chemically assisted ion etching.
